(19) United States
(12) Patent Application Publication
(10) Pub. No.: US 2025/0334890 A1
(43) Pub. Date: Oct. 30, 2025

(54) MODULE FOR A PROJECTION EXPOSURE APPARATUS, METHOD, AND PROJECTION EXPOSURE APPARATUS

(71) Applicant: Carl Zeiss SMT GmbH, Oberkochen (DE)

(72) Inventor: Matthias MANGER, Aalen (DE)

(21) Appl. No.: 19/256,794

(22) Filed: Jul. 1, 2025

Related U.S. Application Data
(63) Continuation of application No. PCT/EP2024/050952, filed on Jan. 17, 2024.

(30) Foreign Application Priority Data
Jan. 20, 2023 (DE) 10 2023 200 422.4

(51) Int. Cl. G03F 7/00; G02B 7/18; H05B 3/00

(52) U.S. Cl. CPC G03F 7/70891; G02B 7/1815; G03F 7/70316; H05B 3/0033

(57) ABSTRACT

A module for a projection exposure apparatus for semiconductor lithography comprises a heating device having at least one radiation source for emitting electromagnetic heating radiation for heating at least regions of a component of the module. The heating device comprises at least one heating element built into the component and configured to convert radiant energy into heat. A corresponding method and a projection exposure apparatus are disclosed.

### CROSS-REFERENCE TO RELATED APPLICATIONS

The present application is a continuation of, and claims benefit under 35 USC 120 to, international application No. PCT/EP2024/050952, filed Jan. 17, 2024, which claims benefit under 35 USC 119 of German Application No. 10 2023 200 422.4, filed Jan. 20, 2023. The entire disclosure of each of these applications is incorporated by reference herein.

### FIELD

The disclosure relates to a module for a projection exposure apparatus having a heatable component, to a method for temperature control of a component, and to a projection exposure apparatus for semiconductor lithography.

### BACKGROUND

Optical elements or else other components of optics of semiconductor lithography systems regularly involve targeted temperature control, often even spatially resolved temperature control. For example, temperature control can help allow manipulation of the optical effect of an optical element for the purpose of correcting aberrations; likewise, a given temperature profile on an optical component can be set and kept constant under variable surroundings.

Various options for the temperature control of the corresponding components have been presented in the past. For example, the applicant's international patent application WO2009/026970 A1 proposed a concept in which a temperature profile in an optical element, defined in terms of its amplitude and spatial design, is set by introducing heating power according to Ohm's law and at the same time implementing defined counter-cooling using a flow of cold gas. This temperature profile leads to a change in the refractive index profile in the material of the optical element, and hence to a deformation of the wavefronts of the light passing through the component.

The international patent application WO2021/089579 A1, also from the applicant, proposes a concept in which there is targeted temperature control as a result of radiating electromagnetic heating radiation into optical elements.

### SUMMARY

The present disclosure seeks to specify a device and a method by which it is possible to achieve an improved spatially resolved temperature control of a component for semiconductor lithography, such as an optical element.

In an aspect, the disclosure provides a module for a projection exposure apparatus for semiconductor lithography. The module comprises a heating device having at least one radiation source for emitting electromagnetic heating radiation for heating at least regions of a component of the module, for example an optical element, for example a lens element or a mirror. In this context, the heating device comprises at least one heating element which is built into the component and configured to convert radiant energy into heat. In contrast with certain known technology, the radiant energy thus is not merely radiated onto an optical element or a component, with comparatively diffuse generation of heat in the irradiated region. Instead, a separate element in which the conversion of radiant energy into heat is implemented in targeted and local fashion is formed in the component. In this way, it is possible already at the design stage of the component to define the approximate point at which, or at least a tightly delimited region in which, the desired heat is released.

For example, the heating element can be an optical resonator, for example a ring resonator. Optical resonators can help make it possible to realize a relatively high density of electromagnetic radiant energy in a comparatively small spatial region, with the result that relatively effective heating by absorption of the electromagnetic radiation can be achieved in locally defined fashion.

The resonator can be a whispering gallery resonator, i.e. a resonator with an extensive resonator zone.

In a variant of the disclosure, the heating element may comprise a region having a periodic refractive index variation, for example a Bragg grating.

By way of two Bragg gratings on a straight waveguide path it is possible to define a conventional Fabry-Pérot resonator as a heating element. Topologically, a ring resonator with an embedded Bragg mirror can correspond to a Fabry-Pérot resonator, which, as it were, is coupled to the light field from the inside. In contrast with the conventional ring resonator, a reflected wave also occurs in that case. Overall, this can help increase the number of degrees of design freedom for obtaining desirable properties.

As a result of the heating device comprising a plurality of heating elements, it is possible to set a desired spatial temperature distribution over a component. When designing the heating elements as resonators, the wavelength selectivity of the resonators can be used in this case for targeted control of individual resonators and hence for targeted spatially resolved heating.

In this case, at least some of the heating elements may be connected in series. A parallel circuit or a mixture of the two aforementioned variants is conceivable.

If the at least one radiation source is configured to emit electromagnetic radiation at a wavelength of the order of 1370 nm, there can be a dissipation of the electromagnetic radiant energy by way of the mechanism of stretch vibrations of hydroxyl groups, as can occur in fused silicas for VUV optics, but also in materials for EUV lithography such as ULE, Zerodur and SuZe, for example, for targeted heating purposes.

The at least one radiation source can be a laser, for example.

In cases where at least one heating element is in the form of a resonator and there is a stabilization circuit for stabilizing the wavelength of the laser, the heating element can find use in a dual role as a resonator for stabilizing the laser.

A tunable laser can allow relatively simple targeted addressing of individual heating elements, for example of individual wavelength-selective resonators.

In a variant of the disclosure, the at least one heating element is formed by a local structural modification in the material of the component. In other words, the heating element is not manufactured separately and subsequently built into the component. Instead, it is created in the component itself, for example in a main body of a multilayer mirror of an EUV projection exposure apparatus, by way of an appropriate treatment.

In this case, the local structural modification to achieve this end may be created by an ion beam, an electron beam, or else a laser beam. There is also the option of creating the local structural modification using a lithographic microstructuring method.

It is conceivable for the at least one heating element to be realized in an optical fiber which, by way of a joining method such as for example adhesive bonding, soldering, welding or fusing, is built into the component to be heated.

In an aspect, the disclosure provides a method of heating at least regions of a component of a module for a projection exposure apparatus for semiconductor lithography via electromagnetic radiation is distinguished in that the electromagnetic radiation is converted into heat in a heating element which is built into the component. As mentioned previously, the heating element can be a resonator and the electromagnetic radiation can be created via a laser.

As mentioned previously, the resonator can be used to stabilize the frequency of the laser. In a variant of the disclosure, it is also conceivable that the resonant frequency of at least one resonator is used to establish physical parameters at the location of the heating element designed as a resonator.

In this case, the aforementioned physical parameters may for example comprise the temperature and/or the expansion of the material at the location of the heating element.

At least one established physical parameter can be used for open-loop or closed-loop control of the heating of the component.

In an embodiment of the disclosure, it is likewise conceivable that at least one established physical parameter is used for open-loop or closed-loop control of an element of the projection exposure apparatus. In this case, the element subject to open-loop or closed-loop control can be a different component to the heated component. For example, the surface shape of the associated optical element, for example a mirror, can be deduced from an established expansion and/or temperature at the location of a heating element. The information thus obtained can then be used to implement corrections of the wavefront by way of a manipulator, downstream in the light path, within the projection exposure apparatus.

It can be desirable for the wavelength of the electromagnetic radiation used to be located in the region of a flank of an absorption line of the material of the heating element. In this way, just a small change in the wavelength can bring about a relatively significant change in the radiant energy converted into heat by absorption.

### BRIEF DESCRIPTION OF THE DRAWINGS

Exemplary embodiments and variants of the disclosure will be explained in more detail hereinafter with reference to the drawing, in which:

FIG. 1 schematically shows a meridional section of a projection exposure apparatus for EUV projection lithography;

FIG. 2 schematically shows a meridional section of a projection exposure apparatus for DUV projection lithography;

FIG. 3 shows a basic schematic;

FIG. 4 shows a schematic illustration of a ring resonator;

FIG. 5 shows sections of the loss spectra of two ring resonators which are operated in ideally matched fashion and have different circumferences;

FIG. 6 shows the power (dissipation and scattering) converted in a ring resonator at resonance, as a function of detuning;

FIG. 7 shows the extinction coefficient of an exemplary fused silica in the near infrared;

FIG. 8 shows a schematic setup of a wave coupler between two dielectric waveguides;

FIG. 9 schematically shows the spectrum of an exemplary ring resonator with a ring circumference of 2 mm, together with the absorption line of the second harmonic of the OH stretching vibration in the case of an assumed refractive index of 1.5;

FIG. 10 shows a variant of the disclosure in which a plurality of resonators are embodied in series;

FIG. 11 shows an overview of possible resonant frequencies for an exemplary group of 21 resonators;

FIG. 12 shows of the associated line spectrum over the wavelength range of interest;

FIG. 13 shows possible absorption spectra for different loss factors;

FIG. 14 shows a block diagram of a PDH stabilization scheme known from the prior art;

FIG. 15 shows a block diagram for a PDH link of a laser source to a mode of a ring resonator;

FIG. 16 shows calculated quadrature components of a PDH signal;

FIGS. 17A-17D show signals around a selected resonance, for different modulation frequencies;

FIG. 18 shows a concept for feeding the radiation from a plurality of laser sources into a chain of ring resonators;

FIGS. 19-22 show possible configurations of coupled resonators; and

FIG. 23 schematically shows an arrangement for writing a waveguide structure into an optical component.

### DETAILED DESCRIPTION

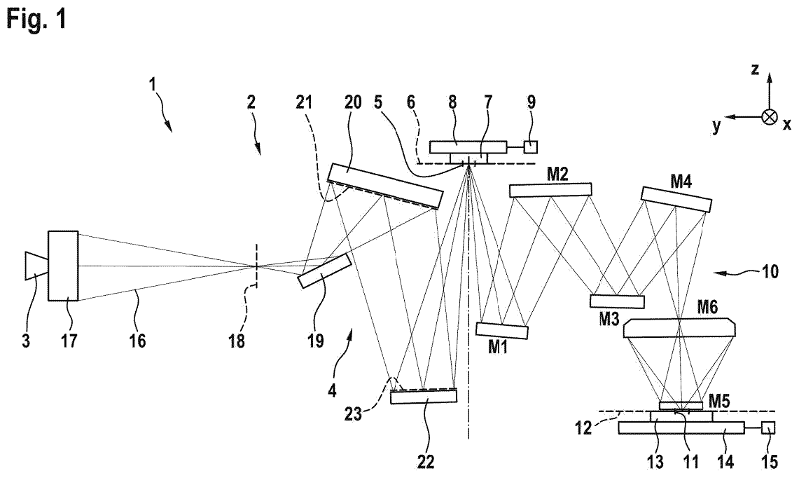

Certain constituent parts of a microlithographic projection exposure apparatus 1, in which the disclosure can be used, are described in exemplary fashion below initially with reference to FIG. 1. The description of the basic setup of the projection exposure apparatus 1 and the constituent parts thereof should not be considered here to be restrictive.

An embodiment of an illumination system 2 of the projection exposure apparatus 1 has, in addition to a light source 3, an illumination optical unit 4 for illuminating an object field 5 in an object plane 6. In an alternative embodiment, the light source 3 may also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable, for example in a scanning direction, by way of a reticle displacement drive 9.

FIG. 1 shows a Cartesian xyz coordinate system by way of elucidation. The x-direction runs perpendicular to the plane of the drawing. The y-direction runs horizontally, and the z-direction runs vertically. The scanning direction runs in the y-direction in FIG. 1. The z-direction runs perpendicular to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable, for example in the y-direction, by way of a wafer displacement drive 15. The displacement firstly of the reticle 7 by way of the reticle displacement drive 9, and secondly of the wafer 13 by way of the wafer displacement drive 15, can be implemented so as to be mutually synchronized.

The radiation source 3 is an EUV radiation source. The radiation source 3 emits EUV radiation 16, which is also referred to below as used radiation, illumination radiation or illumination light. For example, the used radiation has a wavelength in the range between 5 nm and 30 nm. The radiation source 3 may be a plasma source, for example an LPP (laser produced plasma) source or a GDPP (gas discharge produced plasma) source. It may also be a synchrotron-based radiation source. The radiation source 3 may be a free electron laser (FEL).

The illumination radiation 16 emanating from the radiation source 3 is focused by a collector 17. The collector 17 may be a collector with one or more ellipsoidal and/or hyperboloid reflection surfaces. The illumination radiation 16 can be incident on the at least one reflection surface of the collector 17 with grazing incidence (GI), i.e. at angles of incidence of greater than 45° relative to the direction of the normal to the mirror surface, or with normal incidence (NI), i.e. at angles of incidence of less than 45°. The collector 17 may be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 may represent a separation between a radiation source module, having the radiation source 3 and the collector 17, and the illumination optical unit 4.

The illumination optical unit 4 comprises a deflection mirror 19 and, downstream thereof in the beam path, a first facet mirror 20. The deflection mirror 19 can be a plane deflection mirror or, alternatively, a mirror with a beam-influencing effect that goes beyond the purely deflecting effect. As an alternative or in addition, the deflection mirror 19 may be designed as a spectral filter that separates a used light wavelength of the illumination radiation 16 from extraneous light of a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which are also referred to below as field facets. FIG. 1 depicts only some of the facets 21 by way of example.

The first facets 21 may be embodied as macroscopic facets, for example as rectangular facets or as facets with an arcuate or part-circular edge contour. The first facets 21 may be in the form of plane facets or alternatively of facets with convex or concave curvature.

As is known for example from DE 10 2008 009 600 A1, the first facets 21 themselves may also each be composed of a multiplicity of individual mirrors, for example a multiplicity of micromirrors. The first facet mirror 20 may for example be in the form of a microelectromechanical system (MEMS system). For details, reference is made to DE 10 2008 009 600 A1.

The illumination radiation 16 travels horizontally, i.e. in the y-direction, between the collector 17 and the deflection mirror 19.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or may alternatively be facets composed of micromirrors. In this regard, reference is likewise made to DE 10 2008 009 600 A1. The second facets 23 can have plane, convexly curved, or concavely curved reflection surfaces.

The illumination optical unit 4 thus forms a double-faceted system. This basic principle is also referred to as a fly's eye integrator.

It may be desirable to arrange the second facet mirror 22 not exactly in a plane that is optically conjugate to a pupil plane of the projection optical unit 10. For example, the pupil facet mirror 22 may be arranged so as to be tilted relative to a pupil plane of the projection optical unit 10, as described, for example, in DE 10 2017 220 586 A1.

The individual first facets 21 are imaged into the object field 5 using the second facet mirror 22. The second facet mirror 22 is the last beam-shaping mirror or else indeed the last mirror for the illumination radiation 16 in the beam path upstream of the object field 5.

In a further embodiment (not illustrated) of the illumination optical unit 4, a transfer optical unit may be arranged in the beam path between the second facet mirror 22 and the object field 5, and contributes for example to the imaging of the first facets 21 into the object field 5. The transfer optical unit may comprise exactly one mirror or, alternatively, two or more mirrors, which are arranged in succession in the beam path of the illumination optical unit 4. The transmission optical unit can for example comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the field facet mirror 20, and the pupil facet mirror 22.

The deflection mirror 19 may also be omitted in a further design of the illumination optical unit 4, and so the illumination optical unit 4 may then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is often only approximate imaging.

The projection optical unit 10 comprises a plurality of mirrors Mx, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mx are likewise possible. The penultimate mirror M5 and the last mirror M6 each have a through opening for the illumination radiation 16. The projection optical unit 10 is a doubly obscured optical unit. The projection optical unit 10 has an image-side numerical aperture which is greater than 0.5 and which can also be greater than 0.6 and, for example, can be 0.7 or 0.75.

Reflection surfaces of the mirrors Mx can be in the form of free-form surfaces without an axis of rotational symmetry. Alternatively, the reflection surfaces of the mirrors Mx can be designed as aspherical surfaces with exactly one axis of rotational symmetry of the reflection surface shape. Just like the mirrors of the illumination optical unit 4, the mirrors Mx can have highly reflective coatings for the illumination radiation 16. These coatings may be designed as multilayer coatings, for example with alternating layers of molybdenum and silicon.

The projection optical unit 10 has a large object-image offset in the y-direction between a y-coordinate of a center of the object field 5 and a y-coordinate of the center of the image field 11. In the y-direction, this object-image offset can be of approximately the same magnitude as a z-distance between the object plane 6 and the image plane 12.

The projection optical unit 10 may for example have an anamorphic form. For example, it has different imaging scales βx, βy in the x- and y-directions. The two imaging scales βx, By of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in x-direction, i.e. in a direction perpendicular to the scanning direction.

The projection optical unit 10 leads to a reduction in size of 8:1 in y-direction, i.e. in scanning direction.

Other imaging scales are likewise possible. Imaging scales with the same signs and the same absolute values in x-direction and y-direction are also possible, for example with absolute values of 0.125 or 0.25.

The number of intermediate image planes in the x-direction and in the y-direction in the beam path between the object field 5 and the image field 11 may be the same or may differ depending on the design of the projection optical unit 10. Examples of projection optical units with different numbers of such intermediate images in x- and y-directions are known from US 2018/0074303 A1.

One of the pupil facets 23 in each case is assigned to exactly one of the field facets 21, in each case to form an illumination channel for illuminating the object field 5. This may for example result in illumination according to the Köhler principle. The far field is deconstructed into a multiplicity of object fields 5 with the aid of the field facets 21. The field facets 21 generate a plurality of images of the intermediate focus on the pupil facets 23 respectively assigned thereto.

The field facets 21 are imaged, each by way of an assigned pupil facet 23, onto the reticle 7 in a manner such that they are mutually superposed for illumination of the object field 5. The illumination of the object field 5 is for example as homogeneous as possible. It can have a uniformity error of less than 2%. Field uniformity can be achieved by overlaying different illumination channels.

The illumination of the entrance pupil of the projection optical unit 10 may be geometrically defined by an arrangement of the pupil facets. It is possible to set the intensity distribution in the entrance pupil of the projection optical unit 10 by selecting the illumination channels, for example the subset of pupil facets, which guide light. This intensity distribution is also referred to as illumination setting.

A likewise preferred pupil uniformity in the region of sections of an illumination pupil of the illumination optical unit 4 that are illuminated in a defined manner can be achieved by a redistribution of the illumination channels.

Further aspects and details of the illumination of the object field 5 and for example of the entrance pupil of the projection optical unit 10 are described hereinbelow.

The projection optical unit 10 may for example have a homocentric entrance pupil. The latter may be accessible. It may also be inaccessible.

The entrance pupil of the projection optical unit 10 generally cannot be illuminated exactly via the pupil facet mirror 22. The aperture rays often do not intersect at a single point when imaging the projection optical unit 10 which telecentrically images the center of the pupil facet mirror 22 onto the wafer 13. However, it is possible to find an area in which the spacing of the aperture rays that is determined in pairs becomes minimal. This area represents the entrance pupil or an area in real space that is conjugate thereto. For example, this area has a finite curvature.

It may be the case that the projection optical unit 10 has different poses of the entrance pupil for the tangential beam path and for the sagittal beam path. In this case, an imaging element, for example an optical component of the transfer optical unit, should be provided between the second facet mirror 22 and the reticle 7. With the aid of this optical element, the different pose of the tangential entrance pupil and the sagittal entrance pupil can be taken into account.

In the arrangement of the components of the illumination optical unit 4 illustrated in FIG. 1, the pupil facet mirror 22 is arranged in an area conjugate to the entrance pupil of the projection optical unit 10. The field facet mirror 20 is in a tilted arrangement with respect to the object plane 6. The first facet mirror 20 is in a tilted arrangement with respect to an arrangement plane defined by the deflection mirror 19.

The first facet mirror 20 is in a tilted arrangement with respect to an arrangement plane defined by the second facet mirror 22.

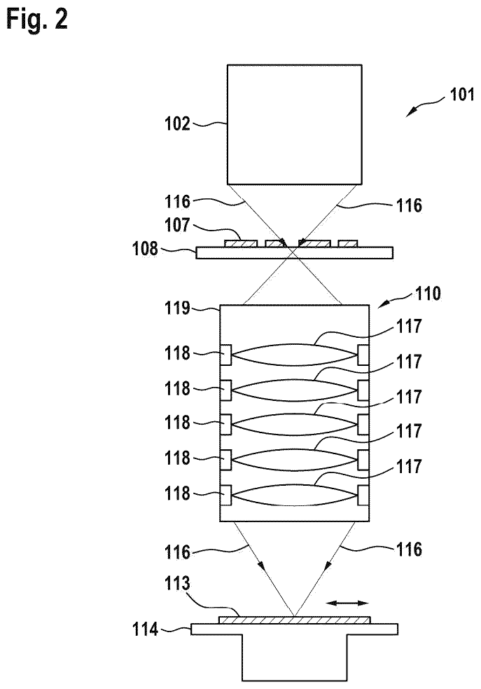

FIG. 2 schematically shows a meridional section through a further projection exposure apparatus 101 for DUV projection lithography, in which the disclosure can likewise be used.

The setup of the projection exposure apparatus 101 and the principle of the imaging are comparable with the setup and procedure described in FIG. 1. Identical component parts are denoted by a reference sign increased by 100 relative to FIG. 1, i.e. the reference signs in FIG. 2 begin with 101.

In contrast to an EUV projection exposure apparatus 1 as described in FIG. 1, refractive, diffractive and/or reflective optical elements 117, such as for example lens elements, mirrors, prisms, terminating plates, and the like, can be used for imaging or for illumination in the DUV projection exposure apparatus 101 on account of the greater wavelength of the DUV radiation 116, employed as used light, in the range from 100 nm to 300 nm, for example of 193 nm. The projection exposure apparatus 101 in this case substantially comprises an illumination system 102, a reticle holder 108 for receiving and exactly positioning a reticle 107 provided with a structure, which determines the later structures on a wafer 113, a wafer holder 114 for holding, moving, and exactly positioning the wafer 113, and a projection lens 110, with a plurality of optical elements 117, which are held by way of mounts 118 in a lens housing 119 of the projection lens 110.

The illumination system 102 provides DUV radiation 116 for the imaging of the reticle 107 on the wafer 113. A laser, a plasma source, or the like can be used as the source of this radiation 116. The radiation 116 is shaped in the illumination system 102 via optical elements such that the DUV radiation 116 has the desired properties with regard to diameter, polarization, shape of the wavefront, and the like, when it is incident on the reticle 107.

Apart from the additional use of refractive optical elements 117, such as lens elements, prisms, terminating plates, the setup of the downstream projection optical unit 101 with the lens housing 119 does not differ in principle from the setup described in FIG. 1 and is therefore not described in further detail.

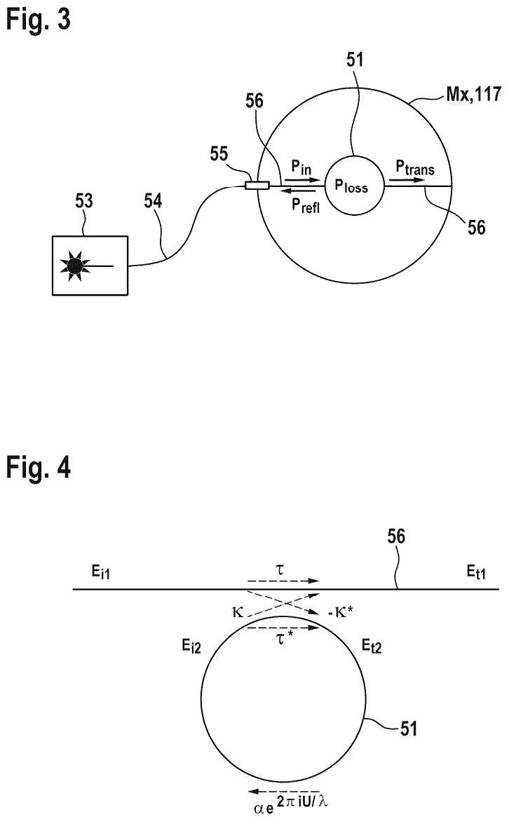

The intention is to explain a principle of the disclosure using the basic schematic depicted in FIG. 3. In accordance with the solution according to the disclosure, a heating element 51, as a photonic integrated circuit (PIC), is built directly into a component, for example the main body of a mirror Mx shown in FIG. 1. The heating radiation, typically provided by a laser source 53 as radiation source, is fed via a supply line designed as an optical fiber 54 and a coupler 55 into a waveguide 56 integrated directly in the component Mx to be heated and is supplied to the heating element 51 likewise embodied in built-in fashion. In the heating element 51 itself, absorption of the radiation leads to the conversion of radiant energy to heat. According to the power balance

$${P}_{i n} = {P}_{refl} + {P}_{trans} + {P}_{l o s s} \qquad ( 1 )$$

the fed-in power Pᵢₙ is split into the power loss Pₗₒₛₛ, the power P_{ref1} reflected by the heating element 51, and the power Pₜᵣₐₙₛ transmitted through the heating element 51. The power loss Pₗₒₛₛ=Pₕₑₐₜ+P_{scat} itself is composed of the heating power Pₕₑₐₜ of interest here and the scattering losses P_{scat}.

An implementation of such a heating element 51 can be realized in the form of a ring resonator for example, as depicted schematically in FIG. 4. The equations for the amplitudes of the electric fields involved are as follows [Rabus 2007]:

$${E}_{t 1} = τ {E}_{i 1} + κ {E}_{i 2} , \qquad ( 2 - 1 )$$

$${E}_{t 2} = - {κ}^{*} {E}_{i 1} + {τ}^{*} {E}_{i 2} \qquad ( 2 - 2 )$$

$${E}_{i 2} = α {e}^{2 π i \frac{n ( λ ) U}{λ}} {E}_{t 2} . \qquad ( 2 - 3 )$$

Eᵢ₁ and Eᵢ₂ herein denote the amplitudes of the waves entering into the two inputs (of the waveguide 56 and ring resonator 51) from the left, and Eₜ₁ and Eₜ₂ denote the waves emerging at the two outputs. The coupling is described by the complex transmission parameter τ and the complex transfer parameter κ, wherein the following applies to reciprocal coupling: τ*τ+κ*κ=1. The ring resonator 51 itself is described by its circumference U, and λ denotes the wavelength of the fed-in radiation and n(λ) denotes the wavelength-dependent refractive index of the substrate material of the component into which the ring resonator 51 is built. The circumferential transmission in the ring resonator 51 for a single revolution is denoted α. The solution to the system of equations 2 can be found in standard textbooks and is:

$${E}_{t 1} = \frac{- α + {te}^{- i θ}}{- α {t}^{*} + {e}^{- i θ}} {E}_{i 1} , \qquad ( 4.1 )$$

$${E}_{i 2} = \frac{- α {κ}^{*}}{- α {t}^{*} + {e}^{- i θ}} {E}_{i 1} , \qquad ( 4.2 )$$

$${E}_{t 2} = \frac{- {κ}^{*}}{1 - α {t}^{*} {e}^{i θ}} {E}_{i 1} . \qquad ( 4.3 )$$

$$θ = \frac{2 π n ( λ ) U}{λ}$$

in this case represents the circumferential phase in the ring resonator 51.

Hence, the following is obtained for the relative transmitted power Pₜ₁:

$${P}_{t 1} = {\vert \frac{{E}_{t 1}}{{E}_{i 1}} \vert}^{2} = \frac{{α}^{2} + {\vert t \vert}^{2} - 2 α \vert t \vert cos ( θ + {φ}_{t} )}{1 + {α}^{2} {\vert t \vert}^{2} - 2 α \vert t \vert cos ( θ + {φ}_{t} )} , \qquad ( 5 )$$

where φₜ=arg(t) denotes the additional phase retardation during the coupling. The following expression arises for the relative power circulating in the ring resonator 51:

$${P}_{i 2} = {\vert \frac{{E}_{i 2}}{{E}_{i 1}} \vert}^{2} = \frac{{α}^{2} ( 1 - {\vert t \vert}^{2} )}{1 + {α}^{2} {\vert t \vert}^{2} - 2 α \vert t \vert cos ( θ + {φ}_{t} )} . \qquad ( 6 )$$

Finally, the following result emerges for the power loss of interest from the balance equation 1 with P_{refl}=0:

$${P}_{loss} = 1 - {P}_{t 1} = \frac{1 - {α}^{2} - {\vert t \vert}^{2} + {α}^{2} {\vert t \vert}^{2}}{1 + {α}^{2} {\vert t \vert}^{2} - 2 α \vert t \vert cos ( θ + {φ}_{t} )} . \qquad ( 7 )$$

Certain conclusions are derived below from the discussion of relationships 5 to 7: If the phase in the argument of the cosine function adopts integer values, θ+φₜ=2πk, where k∈ [symbol] ⁺, then the excitation is in resonance with the electric field in the ring resonator 51. The associated resonant frequencies

$${f}_{k} = \frac{{c}_{0}}{{λ}_{k}}$$

are:

$${f}_{k} = \frac{{c}_{0}}{n ( {λ}_{k} ) U} ( k + \frac{{φ}_{t}}{2 π} ) \approx FSR k , \qquad ( 8 )$$

where c₀ is the speed of light in vacuo. Accordingly, the frequencies of a ring resonator correspond exactly to those of the better-known Fabry-Perot resonator with the free spectral range

$$FSR = \frac{{c}_{0}}{n ( {λ}_{k} ) U}$$

between the equidistant spectral lines in the frequency space. In the case of resonance, the expressions for the powers simplify as:

$${P}_{t 1}^{( res )} = \frac{{( α - \vert t \vert )}^{2}}{{( 1 - α \vert t \vert )}^{2}} \qquad ( 9.1 )$$

$$and$$

$${P}_{loss}^{( res )} = \frac{1 - {α}^{2} - {\vert t \vert}^{2} + {α}^{2} {\vert t \vert}^{2}}{{( 1 - α \vert t \vert )}^{2}} . \qquad ( 9.2 )$$

The transmitted wave disappears if the circumferential transmission a and the coupler transmissivity |t| have identical values. Further, since no reflected wave is present, the input coupled power consequently has been completely converted in the ring resonator 51 in the matching condition α=|t| case.

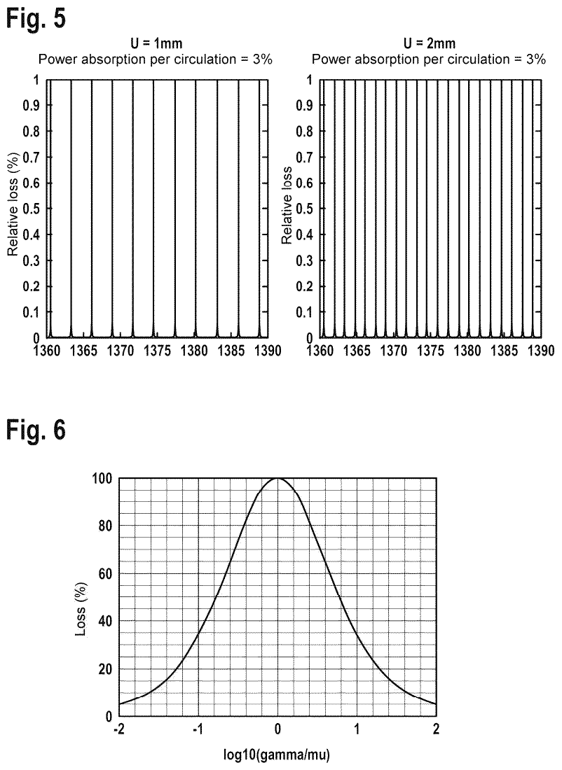

This matching while simultaneously satisfying the resonant condition is chosen as the working point of the radiant heater having a ring resonator. The plots in FIG. 5 each show a section of the loss spectrum of a ring resonator operated in ideally matched fashion, with exemplary ring circumferences U=1.0 mm and U=2.0 mm, for the matched case with α=|t|=\sqrt{1−0.03}≈0.985, corresponding to a respective power loss of 3%

FIG. 6 shows the power (dissipation and scattering) converted in the ring resonator 51 at resonance, as a function of detuning γ/μ. The parameters μ and γ denote the power loss parameters of the configuration corresponding to α=\sqrt{1−μ} and |t|=\sqrt{1−γ}. It is evident from the plot that more than 50% of the fed power in the ring resonator 51 is converted in the form of dissipation or scattering losses within a mismatching interval of 10^{-0.77}−10^{+0.77}=0.17−5.89. For example, if a loss efficiency of >90% is involved in the ring resonator, this means an allowed mismatch of 10^{-0.28}−10^{+0.28}=0.52−1.91.

The following expression is obtained for the width of the resonances in the spectrum once the approximation cos(θ)≈1−θ²/2 and a few elementary computational steps have been implemented:

$$FWHM = FSR \frac{1}{π} \frac{1 - α \vert t \vert}{α \vert t \vert} \approx FSR \frac{1}{π} \frac{γ + μ}{2} , . \qquad ( 10 )$$

In the case of small losses, it is proportional to the mean power loss rate (γ+μ)/2.

The dissipation mechanism underlying the disclosure is explained in more detail below.

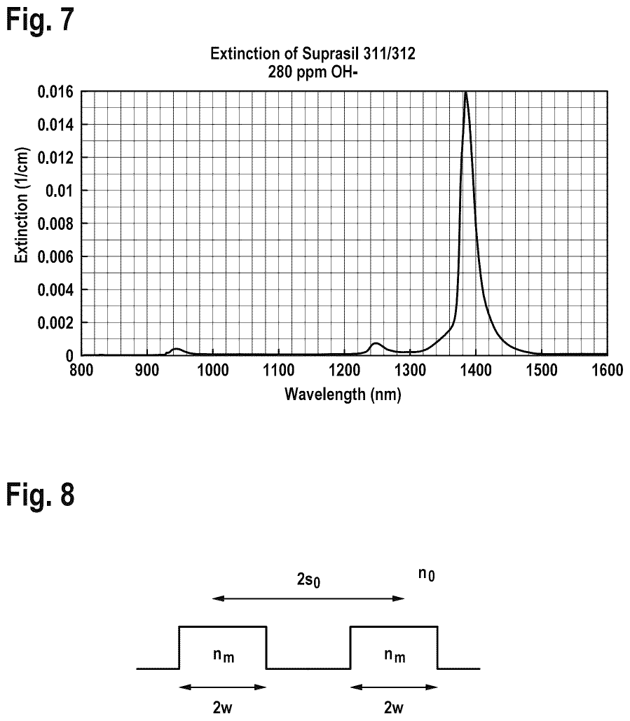

In general, the base material of the glasses used in lithography optics is amorphous silicon dioxide (fused silica). FIG. 7 shows the extinction coefficient of an exemplary fused silica, which finds use for VUV optics in transmission, in the near infrared. The dominant absorption with a peak at approximately 1370 nm originates from the 2nd harmonic of the stretching vibrations of the hydroxyl groups embedded in the glass. The 3rd harmonic of this type of vibration at approximately 950 nm is also quite visible. The absorption at approximately 1250 nm can be attributed to contaminants, typically metal ions. The dominant OH bands are also present in the glasses with vanishing CTE (ULE, Zerodur and SuZe) and therefore lend themselves for use in the heating according to the disclosure with infrared radiation. According to the disclosure, inadvertent (intrinsic) or deliberate doping (homogeneously in the base material, by thermal alloying over the surface or ion implantation) by OH or metal ions can set a desired absorption in the material and hence a loss of power per ring circulation that is as defined as possible. Use can be made of the absorption band around 1370 nm, which belongs to the 2nd harmonic of the OH— stretching vibration and for which the approximate relationship

$${μ}_{diss} ( λ ) = \frac{0.016}{280} {LS}_{OH -} ( λ ) {C}_{OH -} [ ppm ] U [ cm ] \qquad ( 11 )$$

can be derived for the dissipation power loss parameter for single ring circulation. In this case, C_{OH—} denotes the concentration of the OH groups and LS_{OH—}(λ) denotes the normalized lineshape function of the 2nd harmonic with the normalization LS_{OH—}(1370 nm)=1.

Meeting the matching condition μ≈γ is central to the proposed heating principle working. There are a number of options for establishing and/or setting this condition. These will be explained in detail below.

Knowledge about the power loss during a single ring circulation is useful:

$${μ}_{loss} ( λ ) = {μ}_{diss} + {μ}_{scat} . \qquad ( 12 )$$

In embodiments, the losses in the ring resonator 51 are dominated by the dissipative component μ_{diss}. To reduce the scattering and emission losses μ_{scat}, appropriate measures (design of the photonic waveguide and coupler, production and processing, and choice of ring radius) are assumed to have been taken. Once knowledge about these parameters is available, the ring resonator 51 is designed during the actual design step.

In the weak coupling regime, approximately the following expression applies to the symmetric configuration of the coupling parameter illustrated on the basis of FIG. 8:

$$κ \approx \frac{ω cos ( {k}_{t} w )}{2 P ( {k}_{t}^{2} + {α}^{2} )} ( {n}_{m}^{2} - {n}_{0}^{2} ) \sqrt{\frac{π R}{α}} exp ( α ( w - 2 {s}_{0} ) ) \times [ α cos ( {k}_{t} w ) sin h ( α w ) + {k}_{t} sin ( {k}_{t} w ) cos h ( α w ) ] . \qquad ( 13 )$$

The auxiliaries occurring therein are defined as follows:
[symbol] Mode power:

$$P = \frac{β}{2 ω {μ}_{0}} ( w + \frac{1}{α} ) ,$$

[symbol] Transverse propagation constant: kₜ=\sqrt{nₘ²k²−β²},
[symbol] Evanescent decay constant: α=\sqrt{β²−n₀k²}.

Here, FIG. 8 shows a schematic setup of a wave coupler between two dielectric waveguides, with the corresponding parameters: width of the conductors 2w, spacing between the conductors 2s₀, effective refractive index of the guided mode nₘ, and refractive index in the cladding material n₀. The effective radius of curvature of the ring R=r₁r₂/(r₁+r₂) is calculated from the curvatures of the two coupled rings (straight guide: r→∞). The further parameters are defined as follows:
[symbol] Propagation constant: β=nₘk
[symbol] Wavelength and wave number in vacuo: λ, k=2π/λ
[symbol] Angular frequency of the radiation: ω=c₀k
[symbol] Field constants and speed of light in vacuo: μ₀, ε₀, c₀

According to the disclosure, an appropriate choice of the design parameters can help make it possible to sufficiently satisfy the matching condition.

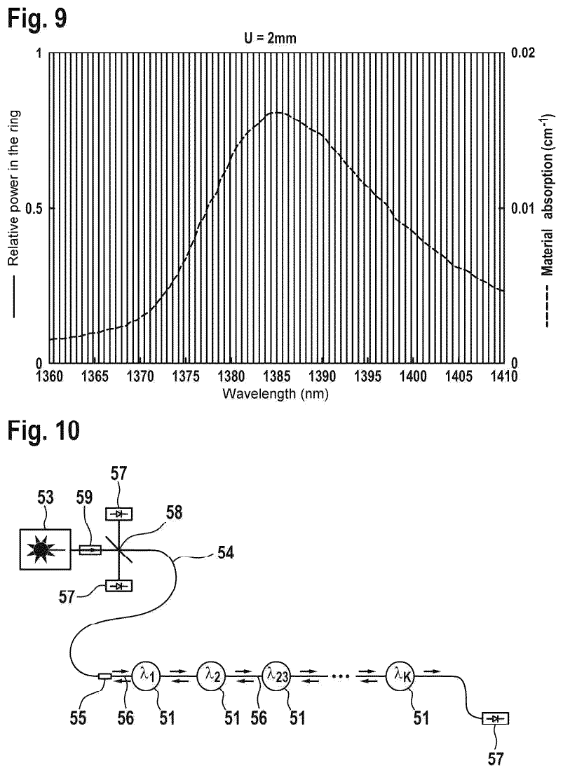

Exploiting the steepness of the absorption line along the sinking or rising flank is desirable for regulating or matching the power during operation or for setting a working point. To this end, the radiant power is fed into the lines of the resonator spectrum optimally assisting the target properties (optimal matching, defined power deposition, . . . ). For illustrative purposes, FIG. 9 schematically shows the spectrum of an exemplary ring resonator with a ring circumference of 2 mm, together with the absorption line of the second harmonic of the OH stretching vibration in the case of an assumed refractive index of 1.5. It is evident from the illustration how the choice of the spectral position of the respective resonator mode in relation to the absorption line of the OH stretching vibration allows the radiant power converted into heat by absorption to be set.

FIG. 10 shows a variant of the disclosure, in which a plurality of resonators, which can be designed for example as ring resonators 51, are embodied in series. It is evident from the figure that a number of ring resonators 51 or other resonators can be connected in series via a single continuous waveguide 56. In this case, appropriate choice of the ring radii allows the individual resonators to operate at defined different wavelengths without crosstalk; i.e. the resonators can be selectively controlled in spatially defined fashion. The individual ring resonators 51 are supplied with radiation via a radiation source designed as an adapted multi-wavelength laser source 53. The powers at the input and output are measured via photosensors 57 for monitoring or control purposes, wherein use is also made of a beam splitter 58 and an optical isolator 59. The photosensors 57 serve to register the power output by the laser source 53 and the reflected and transmitted power. A loss measure can then be determined with knowledge of these three power values. For example, the absorption can be determined if the scattering losses, which likewise contribute to this loss measure, are taken into account, whereby it is possible as a result to draw conclusions about the heating power released at the location of the resonators. In a possible extension to the overall system not depicted in FIG. 10, it is possible to create parallelization by simultaneously implementing a plurality of chains of resonators as heating elements.

The design of the ring resonators in such a chain is considered in detail below. The resonant frequencies of a ring of index j=1, . . . , J with ring circumference U^{(j)} are:

$${f}_{{k}_{j}}^{( j )} = \frac{{c}_{0}}{n ( {λ}_{k} ) {U}^{( j )}} {k}_{j} = {FSR}^{( j )} {k}_{j} . \qquad ( 14 )$$

The goal is that of defining a band in the frequency space in which each resonator can be uniquely assigned a certain frequency such that, by way of a suitable choice of the frequency of the input coupled radiation, a resonator can be addressed in targeted fashion without a resonance arising in the remaining resonators and, connected therewith, an unwanted dissipation and hence heating of the corresponding regions. For a selected reference resonator with a free spectral range FSR⁽⁰⁾ and a given working frequency f₀, the associated mode index is

$${k}_{0}^{( 0 )} = round ( \frac{{f}_{0}}{F S {R}^{( 0 )}} ) . \qquad ( 15 )$$

In the first design step, the mode indices of the resonators at the working frequency are defined as follows:

$${k}_{j}^{( 0 )} = {k}_{0}^{( 0 )} + Δ kj , \qquad ( 16 )$$

where Δk is an integer corresponding to the mode index spacing of two resonators adjacent in frequency. Using this, it is possible according to

$$F S {R}_{j} = \frac{F S {R}^{( 0 )} {k}_{0}^{( 0 )}}{{k}_{j}^{( 0 )}} = F S {R}^{( 0 )} \frac{{k}_{0}^{( 0 )}}{{k}_{0}^{( 0 )} + Δ kj} , \qquad ( 17 )$$

to define the mode spacings of the ring resonators and hence the ring circumferences within a chain. With this choice, the frequencies of the resonators arise as:

$${f}_{{k}_{j}^{( 0 )} + q}^{0 )} = F S {R}^{( 0 )} {k}_{0}^{( 0 )} ( 1 + \frac{q}{{k}_{0}^{( 0 )} + Δ kj} ) \qquad ( 18 )$$

where q is the differential index from the initial position, in which the frequencies of all resonators are degenerate (uniform) according to design.

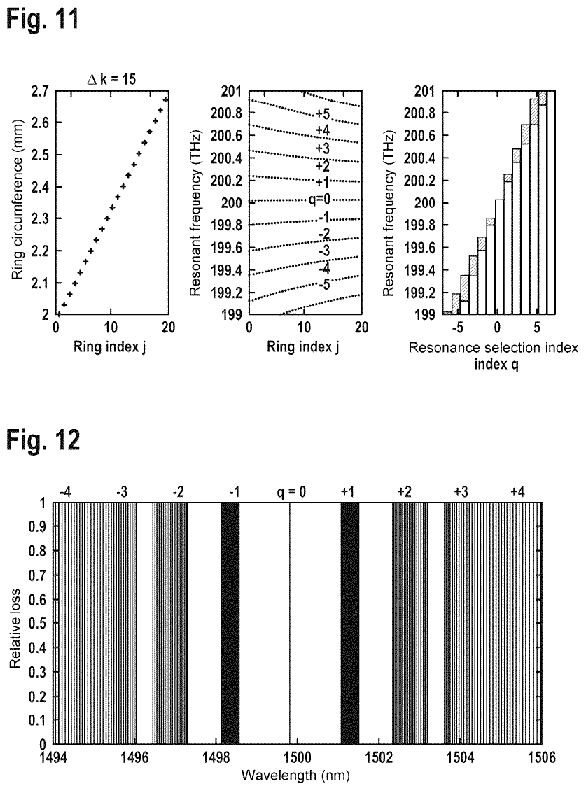

FIG. 11 shows the conditions for an exemplary system design for a chain consisting of 21 resonators connected in series. The left partial figure depicts the ring circumferences for all 21 rings arising from the choice Δk=15.

The central partial figure plots the resonant frequencies for each ring and for different differential indices. It is quite evident from the central partial figure that the resonant frequencies of all 21 rings extend over an ever larger frequency range with increasing absolute value of q; this is elucidated further on the basis of the right partial figure by way of an illustration, depicted with hatching, of the swept frequency ranges.

As illustrated in FIG. 11, the frequencies designed according to equation 18 have the desired property that the spectrum has non-overlapping regions, in which the frequencies assigned to the various resonators of the chain are easily separable. In the given example, non-overlapping frequency bands occur for the values q=±1, ±2. The spread increasing with increasing |q| leads, from |q|≥3, to overlapping and hence no longer separable frequency bands.

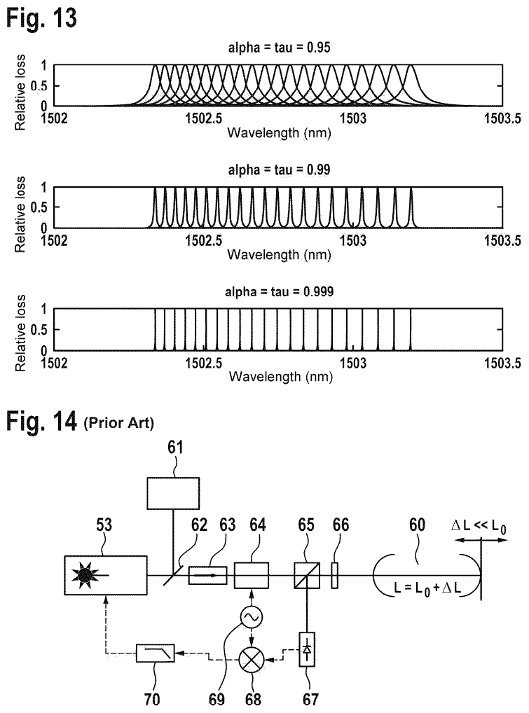

For the exemplary design used, FIG. 12 shows the associated line spectrum over the wavelength range of interest. FIG. 13 plots the absorption spectra for the band with q=+2 in more detail for three exemplary loss factors in the limiting case of ideal matching. It is evident from the illustration that a crosstalk-free control of a specific resonator assumes that there is no overlap of line profiles of adjacent resonators in the frequency space. For the presented design, the line spacing Δf_{q}^{(j)} in a band varies according to the following relationship:

$$Δ {f}_{q}^{( j )} = {f}_{{k}_{1}^{( 0 )} + q}^{( j - 1 )} - {f}_{{k}_{0}^{( 0 )} + q}^{( j )} \approx F S {R}^{( 0 )} \frac{q Δ k}{{k}_{0}^{( 0 )} + Δ kj} . \qquad ( 19 )$$

This spacing is large in comparison with the line width FWHM^{(j)}. This is translated into the following:

$$Δ {f}_{q}^{( j )} > g {FWHM}^{( j )} , \qquad ( 20 )$$

with the acceptance parameter g (typically 10). The line width is given by the circulation losses and the free spectral range, by way of the following relationship:

$${FWHM}^{( j )} = F S {R}^{( j )} \frac{1}{π} \frac{{γ}^{( j )} + {μ}^{( j )}}{2} \qquad ( 21 )$$

. Consequently, the following condition arises for the design of the resonator chain:

$$\frac{{γ}^{( j )} + {μ}^{( j )}}{2} < \frac{π}{g} \frac{F S {R}^{( 0 )}}{{f}_{0}} q Δ k , \qquad ( 22 )$$

in order to obtain the desired sharpness of the resonances.

The most efficient input coupling of the power of the radiation source into the resonators is implemented at the peak of the respective resonance. On account of the desired sharpness of the resonances, using a suitable control method allows frequency-tunable laser sources to be stabilized at the maxima of the selected absorption lines.

Since a change in temperature leads to a resonance shift, also via the change in refractive index and thermal length expansion connected therewith, controlled tracking of the input coupling is at least desirable, if not absolutely mandatory, for the desired resonance sharpnesses. The Pound, Drever, and Hall (PDH) stabilization method can be used as control method.

FIG. 14 shows the block diagram of the PDH stabilization scheme known from the prior art, as used for linking a radiation source in the form of a laser 53 to a resonator 60 designed as a Fabry-Pérot cavity. FIG. 14 also depicts an analyzer 61, a beam splitter 62, an isolator 63, an electro-optic modulator 64, a polarization-dependent beam splitter 65, a quarter wave plate 66, a photodetector designed as a photodiode 67, a mixer 68, a radiofrequency signal 69, and a low-pass filter 70.

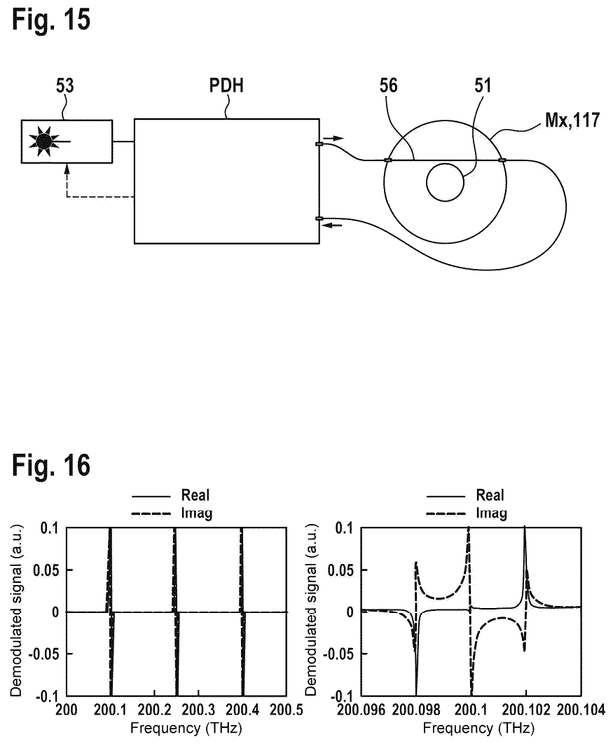

The aforementioned stabilization method is directly adaptable to the coupling of a laser source 53 as a radiation source to the mode of a ring resonator 51. In this case, the transmitted field in the case of the ring resonator 51 can be considered the direct equivalent of the field reflected by the input mirror of a mirror cavity (Fabry-Pérot). From considering this analogy, the block diagram in FIG. 15 arises directly for the PDH link of a laser source 53 to a mode of a ring resonator 51.

The Pound, Drever and Hall method is described extensively in the literature. In this context, particular reference is made to the elaborations by E. D. Black (E. D. Black, Am. J. Phys., Vol. 69, No. 1, January 2001). The functional principle is as follows:

Side bands on the laser radiation fed into the ring resonator 51 are created by the electro-optic modulator 64 (cf. FIG. 14). In the case of a phase modulation of the form

$$φ = β sin ( 2 π {f}_{m} t ) \qquad ( 24 )$$

the complex field strength of the radiation field relevant to the PDH signal and entering the resonator is:

$${E}_{i 1} ( t ) \approx {E}_{0} [ {J}_{0} ( β ) exp ( 2 π {if}_{0} t ) + {J}_{1} ( β ) exp ( 2 π i ( {f}_{0} + {f}_{m} ) t ) - {J}_{1} ( β ) exp ( 2 π i ( {f}_{0} - {f}_{m} ) t ) ] . \qquad ( 23 )$$

Here, β denotes the phase modulation amplitude, fₘ denotes the associated modulation frequency, f₀ denotes the laser frequency, and E₀ denotes the laser amplitude. Jₖ(x) represents a Bessel function of the first kind. The transfer function F between input and output arises directly from equation 4.1 and is

$$F ( f ) = \frac{{E}_{t 1}}{{E}_{i 1}} = \frac{- α + {te}^{- 2 π if / F SR}}{- α t * + {e}^{- 2 π if / FSR}} , \qquad ( 24 )$$

with the free spectral range

$$F S R = \frac{{c}_{0}}{n ( f ) U} .$$

Hence, the light field transmitted at the ring resonator 51 arises as:

$${E}_{t 1} ( t ) = {E}_{0} [ {J}_{0} ( β ) F ( {f}_{0} ) exp ( 2 π {if}_{0} t ) + {J}_{1} ( β ) F ( {f}_{0} + {f}_{m} ) exp ( 2 π i ( {f}_{0} + {f}_{m} ) t ) + ⋯ - {J}_{1} ( β ) F ( {f}_{0} - {f}_{m} ) exp ( 2 π i ( {f}_{0} - {f}_{m} ) t ) ] . \qquad ( 25 )$$

If this light field is incident on the photodetector 67, this yields a photocurrent proportional to the incident power:

$${P}_{t 1} ( t ) = {P}_{c} {\vert F ( {f}_{0} ) \vert}^{2} + {P}_{s} ( {\vert F ( {f}_{0} + {f}_{m} ) \vert}^{2} - {\vert F ( {f}_{0} - {f}_{m} ) \vert}^{2} ) + ⋯ + 2 \sqrt{{P}_{c} {P}_{s}} ℜ ( F ( {f}_{0} ) F * ( {f}_{0} + {f}_{m} ) - F * ( {f}_{0} ) F ( {f}_{0} - {f}_{m} ) ) cos ( 2 π {f}_{m} t ) + ⋯ + 2 \sqrt{{P}_{c} {P}_{s}} 𝔍 ( F ( {f}_{0} ) F * ( {f}_{0} + {f}_{m} ) - F * ( {f}_{0} ) F ( {f}_{0} - {f}_{m} ) ) sin ( 2 π {f}_{m} t ) + ⋯ + + Terms ( [ 2 {f}_{m} ] ) \qquad ( 26 )$$

The radiant powers occurring therein are P_{c}=(E₀J₀(β))² for the carrier and respectively Pₛ=(E₀J₀(β))² for the two side bands. The two quadrature components of the signal oscillating at the modulation frequency fₘ are exposed by demodulation. For illustrative purposes, FIG. 16 shows the calculated quadrature components

$${S}_{PDH 1} = 2 \sqrt{{P}_{c} {P}_{s}} ℜ ( F ( {f}_{0} ) F * ( {f}_{0} + {f}_{m} ) - F * ( {f}_{0} ) F ( {f}_{0} - {f}_{m} ) ) , \qquad ( 27.1 )$$

$${S}_{PDH 2} = 2 \sqrt{{P}_{c} {P}_{s}} 𝔍 ( F ( {f}_{0} ) F * ( {f}_{0} + {f}_{m} ) - F * ( {f}_{0} ) F ( {f}_{0} - {f}_{m} ) ) . \qquad ( 27.2 )$$

of the PDH signal for an exemplary configuration for the case fₘ>>Δf. In this case, the left part of FIG. 16 depicts a section with a width of 3 FSR; the right side depicts an enlarged excerpt for a selected resonance.

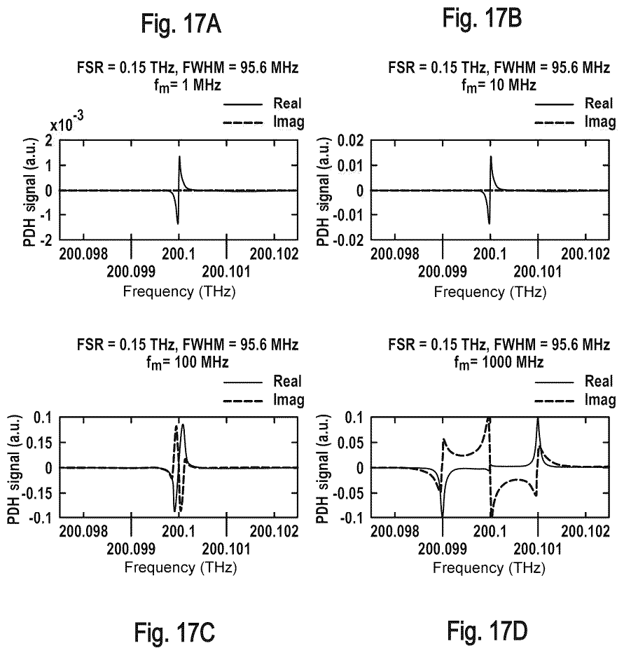

FIGS. 17A-17D plot the signals around a selected resonance, for different modulation frequencies. In metrological applications, fₘ>>FWHM (case d)) is frequently chosen. For this selection, the modulation (dashed curve) oscillating in phase with the excitation signal directly exhibits the most defined and steepest characteristic curve around the resonant frequency. The signal vanishes to zero at the resonance itself. This property is decisive for the success of stabilizing a tunable laser to precisely one mode of a resonator cavity at Hz scales via a PDH control loop. In the less common case fₘ<<FWHM (cases a) and b)), the signal shifted in phase by π/2 (solid curve) is the more suitable signal for laser stabilization.

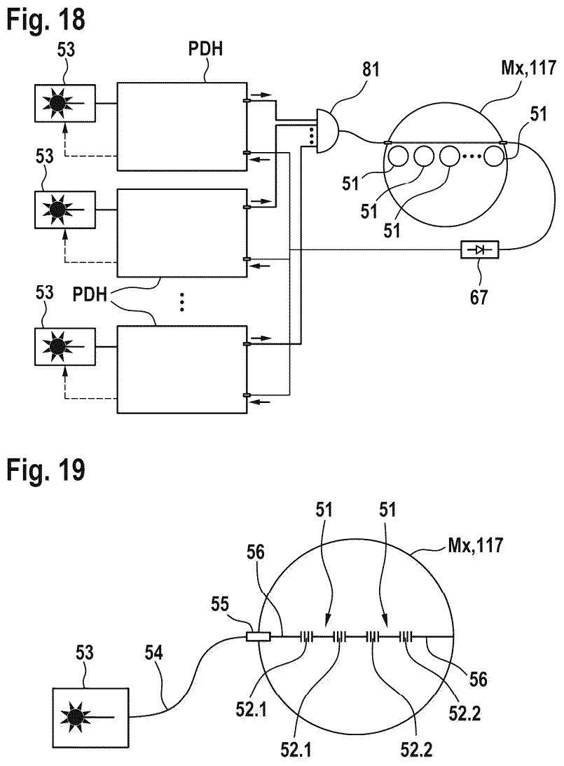

A concept for feeding the radiation of a plurality of laser sources 53 into a chain of ring resonators 51 or heating elements via an optical distributor 81 is illustrated in FIG. 18. Using concepts from integrated optics, such a multi-laser source can in future be integrated, at least in parts, into an electronic photonic chip. In this context, use can be made of phase shifters in order to derive a multiple radiation source from one radiation source, for example a laser source 53, by way of electro-optics.

What is desirable by way of an appropriate design of the modulation frequencies in the case of a chain of resonators 51 and a multiple radiation source is that the beat frequencies occurring at the photodetector 67 can be separated in such a way that crosstalk between the signals is sufficiently suppressed.

The use of a stabilization method for feeding into a selected resonance opens up the possibility of highly accurately determining the frequency or its change, for example by way of a comparison of the laser frequency with a metrological laser frequency comb, by virtue of creating and evaluating a beat signal. Changes in the frequency occur when there are changes in the characteristic optical length (e.g. effective optical circumference of a ring resonator 51) on account of changes in the refractive index of the waveguide material or in the dimension as a consequence of material expansion. As a result, it is possible to obtain, at least indirectly, information about the temperature and/or the expansion. This information can be used to construct and close a control loop.

It is not readily possible to distinguish between the effects of expansion and temperature. However, expansion and temperature are completely correlated in the case of thermal actuation, with the result that, following an appropriate calibration, the signal obtained directly represents the effect to be attained.

There are a large number of design options based on the presented principle. By way of example, use can be made of more complex configurations with ring resonators 51 coupled in series and/or in parallel, with and without Bragg gratings. It may also be desirable to provide a read line. FIGS. 19 to 22 serve illustrative purposes.

In this case, FIG. 19 shows an exemplary illustration of two series-connected Fabry- Perot resonators 51 as heating elements in a mirror Mx, 117. In this case, the resonators are fed from the radiation source 53 via the supply line 54 and the coupler 55 connected to the waveguide 56. For example, the coupler 55 can be a fiber plug or else a splice. In this case, each Fabry-Perot resonator 51 is implemented using two Bragg gratings 52.1 and 52.2. In this case, a certain wavelength selectivity of the resonators 51 can be set over a wide range by way of the periodicity of the Bragg gratings 52.1 and 52.2 used. The Bragg gratings 52.1 and 52.2 can be produced differently in this case. For example, it is possible to make use of the photosensitive effect of the material used, the photosensitive effect substantially bringing about a local small change in refractive index of the material under the action of UV radiation. For example, if a periodic intensity modulation is created in the material via a phase mask, then this is reflected in a corresponding local, periodic refractive index modulation, with the result that the created structure acts as a wavelength-selective mirror. The reflection spectrum of such a mirror can be influenced by setting the amplitude of the modulation, and also by a suitable, optionally also changing periodicity of the grating created. In the latter case, this is referred to as a chirped grating. The described production method makes it possible to integrate the desired structures contactlessly on the mirror Mx, 117, merely by way of the action of suitable electromagnetic radiation. It is likewise conceivable to fabricate the desired structures in advance and subsequently apply these to the mirror Mx, 117.

For example, the waveguide 56 can also be connected to the supply line 54 by joining methods such as adhesive bonding, soldering, welding, fusing.

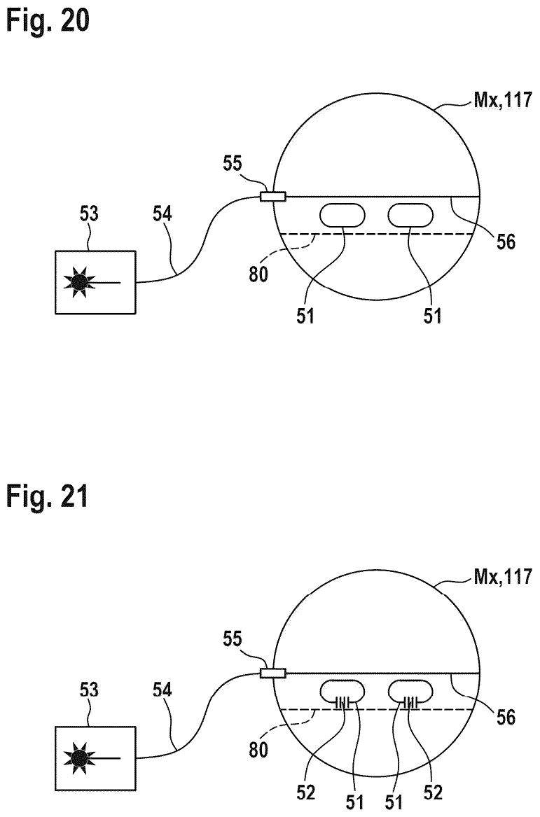

FIG. 20 shows a variant of the disclosure in which two series-connected ring resonators 51 are fed by the waveguide 56. In this case, the ring resonators 51 may have been integrated in the mirror Mx, 117 during production, or else attached at a later stage. An optional read line 80 is also depicted in the figure using a dashed line; it can be used to provide further signals for controlling the arrangement.

FIG. 21 depicts an embodiment of the disclosure in which a combination of ring resonators 51 and Bragg gratings 52 is used.

As a result of integrating the Bragg gratings 52 it is possible to redesign the ring resonators 51 as conventional Fabry-Pérot resonators, wherein this results in a circulation of the electric field that alternates in the sense of rotation as a consequence of the two-sided reflection at the Bragg grating 52 rather than a circulation of the electric field that is unchanging in the sense of rotation. The resonator is fed no longer from the outside but internally via the coupling site which is then located within the actual resonator. In contrast with the simple ring resonator, a reflected wave occurs again as a consequence of the field alternating in the sense of rotation of the circulation.

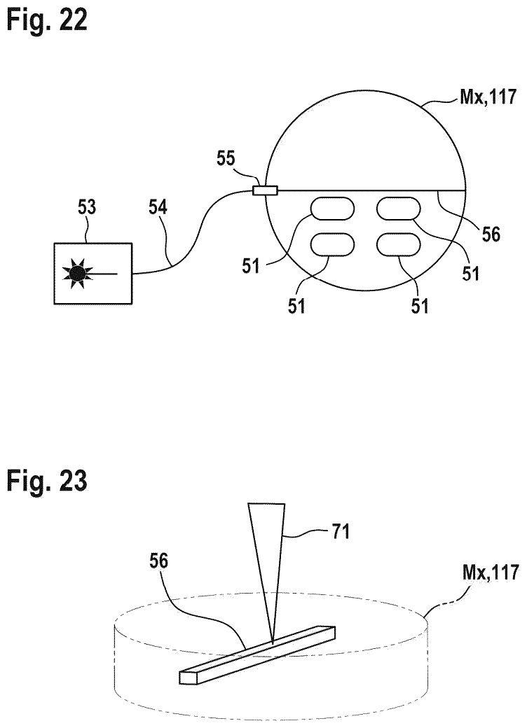

FIG. 22 shows a variant in which a plurality of ring resonators 51 mutually couple into one another. So-called whispering gallery mode resonators, which have an extensive resonator zone rather than a ring, are also conceivable for the application. The degrees of design freedom additionally arising in the process can be used to the benefit of channel separation, coupling efficiency, or signal obtention.

It is self-evident that the variants explained are purely exemplary and non-limiting options for implementing the disclosure. Extensions and modifications are conceivable and desirable depending on the use case.

Lithographic and/or beam-based methods come into question as manufacturing technologies for the waveguide structures involved in fused silica or fused silica ceramics. The beam-based methods, by which local and persistent changes in the refractive index can be brought about in the material without further material (e.g. Si) coming into play, seem to be particularly desirable in this case. In this case, a light-guiding region forms by way of a local increase in the refractive index vis-à-vis the surroundings. In principle, by way of a writing process, functional photonic structures can be defined in three dimensions via irradiation. In this case, use is made of
laser beams,
ion beams,
electron beams.

FIG. 23 schematically shows a corresponding arrangement. In this case, a waveguide structure 56 is written into an optical component Mx via a focused beam 71. For example, the beam 71 can be a laser beam, ion beam, or electron beam.

### LIST OF REFERENCE SIGNS

1 Projection exposure apparatus
2 Illumination system
3 Radiation source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
51 Ring resonator
52 Bragg grating
53 Radiation source
54 Supply line
55 Coupler
56 Waveguide
57 Photosensor
58 Beam splitter
59 Optical isolator
60 Resonator
61 Analyzer
62 Beam splitter
63 Isolator
64 Electro-optic modulator
65 Polarization-dependent beam splitter
66 Quarter wave plate
67 Photodetector
68 Mixer
69 Radiofrequency signal
70 Low-pass filter
71 Focused beam
80 Read line
81 Optical distributor
101 Projection exposure apparatus
102 Illumination system
107 Reticle
108 Reticle holder
110 Projection optical unit
113 Wafer
114 Wafer holder
116 DUV radiation
117 Optical element
118 Mounts
119 Lens housing
M1-M6 Mirrors

1. A module, comprising:
a component; and
a heating device, comprising:
a radiation source configured to emit electromagnetic heating radiation to heat regions of the component; and
a heating element built into the component,
wherein the heating element is configured to convert the electromagnetic radiation into heat.

2. The module of claim 1, wherein the heating element comprises an optical resonator.

3. The module of claim 1, wherein the heating element comprises a ring resonator.

4. The module of claim 1, wherein the heating element comprises a a whispering gallery resonator.

5. The module of claim 1, wherein the heating element comprises a region having a periodic refractive index variation.

6. The module of claim 1, wherein the heating device comprises a plurality of heating elements.

7. The module of claim 6, wherein at least some of the heating elements are connected in series.

8. The module of claim 6, wherein at least some of the heating elements are connected in parallel.

9. The module of claim 1, wherein the radiation source is configured to emit electromagnetic radiation at a wavelength of the order of 1370 nm.

10. The module of claim 1, wherein the radiation source comprises a laser.

11. The module of claim 10, wherein the heating element comprises a resonator, the module comprises a stabilization circuit configured to stabilize a wavelength of the electromagnetic radiation emitted by the laser.

12. The module of claim 1, wherein the radiation source comprises a tunable laser.

13. The module of claim 1, wherein the heating element comprises a local structural modification in a material of the component.

14. The module of claim 13, wherein the local structural modification is created by an ion beam, an electron beam, a laser beam, or a lithographic microstructuring method.

15. The module of claim 1, wherein the heating element comprises an optical fiber.

16. The module of claim 1, wherein the component comprises a mirror.

17. An apparatus, comprising:
a module according to claim 1,
wherein the apparatus is a semiconductor lithography projection exposure apparatus.

18. A module, comprising:
a component comprising a heating element; and
a radiation source configured to emit electromagnetic heating radiation to heat regions of the component,
wherein the heating element is configured to convert the electromagnetic radiation into heat.

19. An apparatus, comprising:
a module according to claim 18,
wherein the apparatus is a semiconductor lithography projection exposure apparatus.

20. A method of heating regions of a component of a module for a projection exposure apparatus for semiconductor lithography using electromagnetic radiation, the method comprising:
converting the electromagnetic radiation into heat via a heating element built into the component.

21.-28. (canceled)
